(19) United States
(12) Patent Application Publication
(10) Pub. No.: US 2026/0253844 A1
(43) Pub. Date: Aug. 27, 2026

(54) METALENS PREPARATION METHOD, METALENS, AND USE THEREOF

(71) Applicant: Advanced Micro-Fabrication Equipment Inc. China, Shanghai (CN)

(72) Inventors: Linfeng BAI, Shanghai (CN); Qiuping HUANG, Shanghai (CN)

(21) Appl. No.: 19/161,119

(22) PCT Filed: Feb. 28, 2024
(86) PCT No.: PCT/CN2024/079023

§ 371 Date: Aug. 29, 2025

(30) Foreign Application Priority Data
Mar. 24, 2023 (CN) 202310301274.3

(51) Int. Cl. H01J 37/32; G02B 1/00

(52) U.S. Cl. CPC H01J 37/32449; G02B 1/00; H01J 2237/334

(57) ABSTRACT

Disclosed in the present invention are a metalens preparation method, a metalens, and use thereof. The metalens preparation method includes: providing a plasma processing device comprising a plasma processing chamber, wherein the plasma processing chamber is capable of providing a radio frequency environment therein and is provided with an electrostatic chuck therein; transferring a glass substrate onto the electrostatic chuck, wherein the glass substrate comprises a glass base layer, a TiO₂ coating is formed on a surface of the glass base layer, and a patterned mask layer is disposed on a surface of the TiO₂ coating; and introducing etching gases into the plasma processing chamber, wherein the etching gases are dissociated into plasma under the radio frequency environment, and the plasma etches the glass substrate to form a TiO₂ nanostructure. According to the present invention, the high-aspect-ratio TiO₂ nanostructure is prepared on the glass base layer through a plasma etching method. No visible marks exist after etching, thereby enhancing the yield of metalenses and enabling high-quality mass manufacturing of metalenses.

### CROSS REFERENCE TO RELATED APPLICATION

This application is a national phase application of International Application No. PCT/CN2024/079023, filed on Feb. 28, 2024, which claims priority to Chinese Application No. 202310301274.3, filed on Mar. 24, 2023. All of the above-referenced applications are incorporated herein by reference in their entirety.

### TECHNICAL FIELD

The present invention belongs to the field of optical elements, and particularly relates to a metalens preparation method, a metalens, and use thereof.

### BACKGROUND

Traditional lens designs typically utilize convex or concave shapes to focus or expand incident light beams. While near-ideal focusing can be achieved on the optical axis, the resulting image may be distorted due to light passing through other lens regions. Correcting lens aberrations typically means creating custom lenses or multiple optical assemblies, and this increases device weight, volume, and cost. If changing the focus position or translating the light beam is needed for the device, lens groups need to be moved, and this may further lead to system instability.

Diffractive lenses offer certain advantages over traditional lenses because they are planar in structure and relatively easily manufactured at low costs. However, higher-order diffracted light of diffractive lenses limits achievable image quality, particularly for high-precision imaging fields.

Metalenses, also known as metasurface lenses, are two-dimensional planar lens structures using metasurfaces (planar two-dimensional metamaterials having a subwavelength thickness) to focus light. The metasurfaces are a series of artificial antennas that can manipulate optical responses of incident light, including amplitude, phase, and polarization. The flat characteristic of the metasurfaces further facilitates avoiding image anamorphic distortion common in traditional curved lenses. The potential of the metalenses for performing complex wavefront engineering within a single optical element is very attractive for a series of applications. The metalenses feature a smaller lens size, enabling device miniaturization, arbitrary optical wave regulation, enhanced optical stability, and better focusing quality than traditional lenses, and thus the metalenses are an ideal alternative to traditional lenses.

However, manufacturing metalenses is not easy due to the requirement for high-precision design of microstructures to generate the required focusing or other specific behaviors on the metasurface. How to manufacture metalenses cost-effectively is still a significant challenge at present.

### SUMMARY

An objective of the present invention is to provide a metalens preparation method that is low in cost, mass-producible, and high in yield.

To achieve the objective, the present invention provides a metalens preparation method, comprising:
providing a plasma processing device comprising a plasma processing chamber, wherein the plasma processing chamber is capable of providing a radio frequency environment therein and is provided with an electrostatic chuck therein;
transferring a glass substrate onto the electrostatic chuck, wherein the glass substrate comprises a glass base layer, a TiO₂ coating is formed on a surface of the glass base layer, and a patterned mask layer is disposed on a surface of the TiO₂ coating; and
introducing etching gases into the plasma processing chamber, wherein the etching gases are dissociated into plasma under the radio frequency environment, and the plasma etches the glass substrate to form a TiO₂ nanostructure.

In an embodiment, the etching gases comprise Cl₂.

In an embodiment, the etching gases further comprise a CₓH_{y}F_{z} gas as an etching-enhancing gas, wherein 0<x≤4, y≥0, z≥0, and y and z are not simultaneously 0.

In an embodiment, the CₓH_{y}F_{z} gas is C₄F₈.

In an embodiment, in the CₓH_{y}F_{z} gas, x<2.

In an embodiment, the CₓH_{y}F_{z} gas comprises any one or more of CHF₃, CH₂F₂, CH₃F, CF₄, and CH₄.

In an embodiment, during etching, an adsorption electrode is disposed within the electrostatic chuck, and a voltage applied to the adsorption electrode is greater than 4,500 V.

In an embodiment, during etching, the voltage is 5,000 V to 10,000 V.

In an embodiment, during etching, a backside helium gas pressure of the electrostatic chuck is 18 Torr to 25 Torr.

In an embodiment, the metalens preparation method further comprises: removing the mask layer after forming the TiO₂ nanostructure.

In an embodiment, the mask layer is a photoresist layer;
or the mask layer comprises a photoresist layer and a hard mask layer disposed beneath the photoresist layer.

The present invention further provides a metalens prepared according to the metalens preparation method, comprising: a glass base layer and a TiO₂ nanostructure formed on a surface of the glass base layer, wherein the TiO₂ nanostructure is arranged in an array.

In an embodiment, the nanostructure comprises a plurality of columns, and trenches are formed between adjacent columns.

In an embodiment, the nanostructure has a high aspect ratio that refers to a ratio of an opening width to a depth of the trenches being greater than 1:1.

In an embodiment, a thickness of the glass base layer is 300 μm to 700 μm.

The present invention further provides use of the metalens, wherein the metalens is used in an optical element.

In an embodiment, the metalens is used in VR and AR lenses.

Compared with the prior art, the present invention has at least the following beneficial effects:
1) The high-aspect-ratio TiO₂ nanostructure is prepared on the glass base layer through a plasma etching method, and can be used for metasurfaces of metalenses.
2) The CₓH_{y}F_{z} gas is selected as an etching-enhancing gas, effectively reducing temperature sensitivity of the glass substrate and eliminating visible marks caused by local temperature differences due to temperature sensitivity of glass, thereby enhancing the yield of metalenses.
3) Suitable conditions for adsorption electrode voltage and backside helium gas pressure are found. By appropriately increasing the backside helium gas pressure of the electrostatic chuck, the temperature uniformity of the glass substrate during etching is enhanced, avoiding visible marks caused by local temperature differences, further enhancing the yield of metalenses, and enabling high-quality mass manufacturing of metalenses.

### BRIEF DESCRIPTION OF THE DRAWINGS

FIG. 1 shows a process flowchart of a metalens preparation method according to the present invention.

FIG. 2 shows a schematic structural diagram of an inductively coupled plasma reactor 200 adopted in Embodiments 1-2 according to the present invention.

FIG. 3 shows a schematic structural diagram of a to-be-processed glass substrate 1 according to the present invention.

FIG. 4 shows a schematic structural diagram of a metalens according to the present invention.

FIG. 5 shows a schematic structural diagram of an inductively coupled plasma reactor 500 adopted in Embodiments 3-4 according to the present invention.

### DETAILED DESCRIPTION

The technical solutions of the present invention will be clearly and intactly described below in conjunction with the drawings. It is apparent that the embodiments described are a part of the embodiments of the present invention rather than all of them. Based on the embodiments of the present invention, all other embodiments obtained by those of ordinary skill in the art without creative work fall within the protection scope of the present invention.

In the description of the present invention, it needs to be noted that the terms “upper”, “lower”, “left”, “right”, “vertical”, “horizontal”, “inside”, “outside”, etc. refer to the orientation or position relationship based on the orientation or position relationship shown in the drawings, which is only for the convenience of describing the present invention and simplifying the description, and not to indicate or imply that the device or component referred to must have a specific orientation, be constructed and operated in a specific orientation. Therefore, the above terms cannot be understood as a limitation on the present invention. In addition, the terms “first”, “second”, and “third” are used merely for descriptive purposes and are not to be construed as indicating or implying relative importance.

In the description of the present invention, it needs to be noted that unless otherwise expressly specified and defined, the terms “mount”, “connecting”, and “connection” should be broadly understood. For example, they may refer to fixed connections, detachable connections, or integrated connections; may refer to mechanical connections; and may refer to direct connections, indirect connections through intermediary media, or internal communication between two components. Those of ordinary skill in the art can understand the specific meanings of the above terms in the present invention in specific situations.

To provide a compact integrated optical system and meet people's higher requirements for lenses, such as smallest possible volume, lightest possible weight, and highest possible image quality, metalenses have become a potential solution.

Existing metalens processing methods each have drawbacks:
1) Lithography, whose disadvantages lie in numerous processing steps and limited material choices;
2) Electron beam lithography (EBL), but it has low yield, high processing costs, and significant proximity effects;
3) Nanoimprint lithography (NIL), whose main disadvantages include errors during pattern transfer, high template manufacturing costs, and limited template lifespan;
4) Femtosecond laser direct writing (two-photon polymerization, TTP), but it has a long manufacturing cycle.

Metalenses have two main types of metasurface structures: dielectric or plasmonic materials. TiO₂, as a dielectric material with a transparent window in the visible spectrum, is applied in the present invention to the metasurface of metalenses to prepare a TiO₂ nanostructure on a glass base layer. The trenches of the TiO₂ nanostructure have a high aspect ratio, such as a ratio of an opening width to a depth of the trenches being greater than 1:1. However, the aforementioned traditional metalens preparation methods are difficult to obtain high-quality and high-aspect-ratio TiO₂ nanostructures, while high-quality and high-aspect-ratio nanostructures are crucial for the optical performance of metalenses.

The present invention innovatively adopts plasma etching to obtain the high-aspect-ratio TiO₂ nanostructure for metalens preparation.

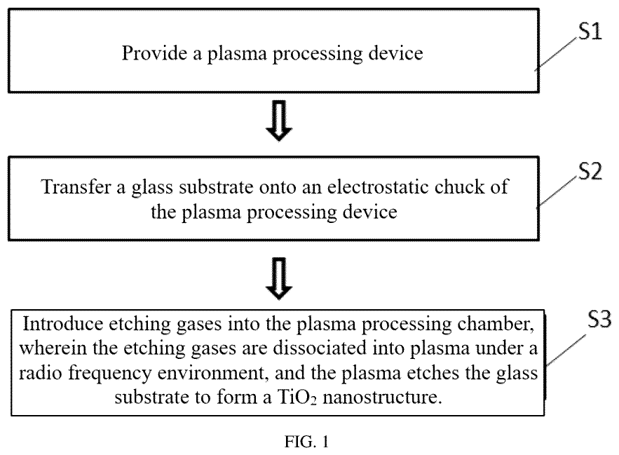

As shown in FIG. 1, a metalens preparation method according to the present invention includes the following steps:

S1, providing a plasma processing device.

The plasma processing device may be an inductively coupled plasma (ICP) reactor or a capacitively coupled plasma (CCP) reactor. The plasma processing device includes a plasma processing chamber. The plasma processing chamber is capable of providing a radio frequency environment therein and is provided with an electrostatic chuck therein. The radio frequency environment is used for providing plasma. An adsorption electrode is further disposed within the electrostatic chuck. A voltage can be applied to the adsorption electrode.

S2, transferring a glass substrate onto an electrostatic chuck of the plasma processing device.

The glass substrate includes a glass base layer. A TiO₂ coating is formed on the surface of the glass base layer. A patterned mask layer is formed on the surface of the TiO₂ coating. The glass base layer according to the present invention includes silicon dioxide, and may also include other impurities. The mask layer according to the present invention may be a photoresist layer. To improve the etching selectivity between the mask layer and the TiO₂ coating, a hard mask layer may also be disposed beneath the photoresist layer, and the two together serve as an etching mask layer for the TiO₂ coating.

The thickness of the glass base layer is 300 μm to 700 μm. The thickness of the TiO₂ coating depends on the thickness of the nanostructure to be prepared.

The mask layer is used for protecting the TiO₂ nanostructures to be formed, and exposing parts requiring etching.

S3, introducing etching gases into the plasma processing chamber, wherein the etching gases are dissociated into plasma under the radio frequency environment, and the plasma etches the glass substrate to form a TiO₂ nanostructure.

The nanostructure described herein refers to that the dimensions of each structural unit, such as thickness (height) and width, are at nanometer scale.

In this embodiment, the etching gases include Cl₂. It can be understood that other conventional etching gases used for TiO₂ coating etching may also be used in the present invention.

Due to the poor thermal conductivity of the glass substrate, during plasma etching, minor local temperature differences on the surface of the glass substrate may cause differences in the thickness of nanostructures after plasma etching, and further present visible marks on the surface of the metalens. These visible marks can affect the optical performance of metalenses, resulting in reduced yield of batch production.

To solve the problem of visible marks, the present invention makes improvements from the following two directions:
1) Reduce the temperature sensitivity of the glass substrate during etching;
2) Enhance the temperature uniformity of the glass substrate during etching.

To reduce the temperature sensitivity of the glass substrate during etching, in the present invention, the CₓH_{y}F_{z} gas, as an etching-enhancing gas, is further introduced into the plasma processing chamber, wherein 0<x≤4, y≥0, z≥0, and y and z are not simultaneously 0. For example, the CₓH_{y}F_{z} gas is C₄F₈.

Through experiments, it is found that the shorter the carbon chain of the CₓH_{y}F_{z} gas, the more significant the effect of reducing temperature sensitivity, such as x<2.

The following will be described in conjunction with Embodiments 1-2.

### Embodiment 1

An inductively coupled plasma (ICP) reactor is adopted to prepare metalenses, and the temperature sensitivity of a glass substrate under different etching gases is tested.

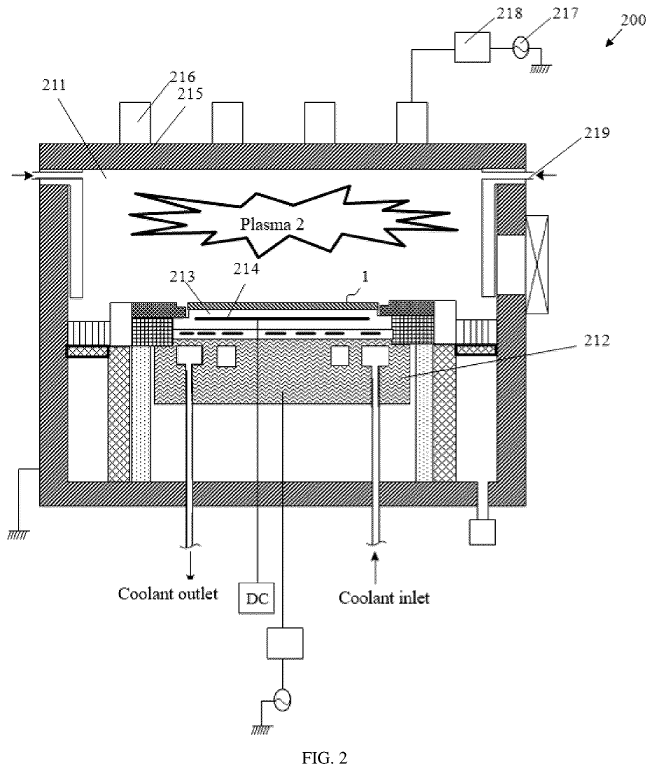

As shown in FIG. 2, an ICP reactor 200 includes a plasma processing chamber 211, a base 212 is disposed downstream of the plasma processing chamber 211, an electrostatic chuck 213 is disposed on the base 212, and an adsorption electrode 214 is disposed within the electrostatic chuck 213 and used for generating electrostatic adsorption force to secure a to-be-processed glass substrate 1 during the process. An insulating window 215 is disposed above the plasma processing chamber 211. Inductively coupled coils 216 are disposed above the insulating window 215. A radio frequency power source 217 applies a radio frequency voltage to the inductively coupled coils 216 via a radio frequency matching network 218. At least one gas injection opening 219 is disposed on the sidewall of the plasma processing chamber 211 and used for injecting process gases into the plasma processing chamber 211. The radio frequency power from the radio frequency power source 217 drives the inductively coupled coils 216 to generate high-frequency alternating magnetic fields, such that low-pressure process gases within the plasma processing chamber 211 are ionized to generate plasma 2. The plasma 2 contains a substantial quantity of reactive species, including electrons, ions, excited-state atoms, molecules, and free radicals. These reactive species can undergo diverse physical and chemical reactions with the surface of the to-be-processed glass substrate 1, thereby modifying the surface topography of the substrate and completing the etching process.

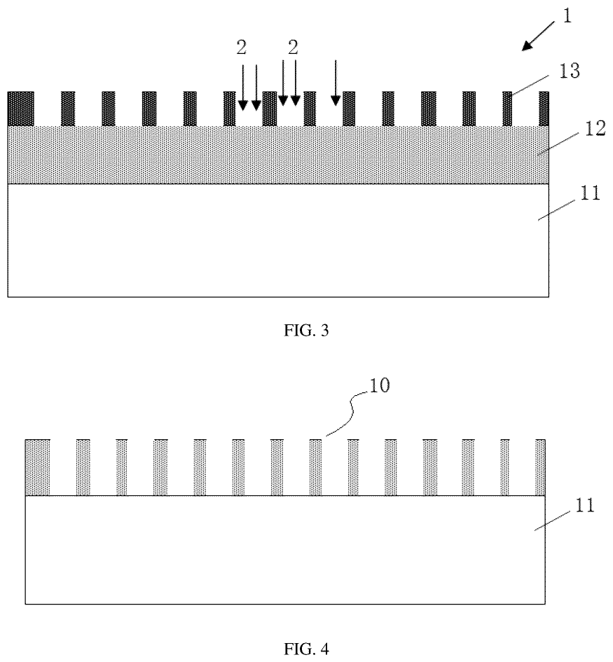

A glass substrate 1 is transferred onto the electrostatic chuck 213. As shown in FIG. 3, the glass substrate 1 includes a glass base layer 11, a TiO₂ coating 12 is formed on the surface of the glass base layer, and a patterned mask layer 13 is formed on the surface of the TiO₂ coating. The thickness of the TiO₂ coating 12 depends on the height of the TiO₂ nanostructure to be prepared, with both dimensions being equivalent. The TiO₂ nanostructure, as a metasurface dielectric layer, has a height that is typically less than the wavelength.

The temperature of the electrostatic chuck 213 is controlled at 40° C. A mixture of etching gases C4F8 and Cl2 (a volume ratio of Cl2 to C4F8 being 4:1) is introduced into the plasma processing chamber 211 for 80 seconds. The etching gases are dissociated into plasma 2 under the radio frequency environment. The plasma 2 etches the TiO₂ coating 12 on the glass substrate 1 that is unprotected by the mask layer 13, thereby forming a TiO₂ nanostructure 10 (see FIG. 4). In this embodiment, the TiO₂ nanostructure is arranged in an array of columns, with each TiO₂ nanocolumn having a height of 127 nm. In some embodiments, the TiO₂ nanostructure may also be line-shaped. The glass substrate 1 is taken out from the plasma processing chamber 211. After the mask layer 13 is removed, a metalens is obtained.

As shown in FIG. 4, the metalens of the present invention includes: a glass base layer 11 and a TiO₂ nanostructure 10 formed on the surface of the glass base layer. The TiO₂ nanostructure is arranged in an array.

In this embodiment, the nanostructure includes a plurality of nanocolumn structural units, and trenches are formed by adjacent columns. In other embodiments, the TiO₂ nanostructure may also be arranged in different manners.

After the plasma processing chamber 211 is thoroughly cleaned, another identical to-be-processed glass substrate 1 is placed on the electrostatic chuck 213. The temperature of the electrostatic chuck 213 is controlled at 45° C. A mixture of etching gases C₄F₈ and Cl₂ is introduced into the plasma processing chamber 211 for 30 seconds. The etching gases are dissociated into plasma 2 under the radio frequency environment. The plasma 2 etches the TiO₂ coating 12 on the glass substrate 1 that is unprotected by the mask layer 13, thereby forming a TiO₂ nanostructure 10. The measured height of the TiO₂ nanocolumns is 146 nm.

It can be seen by calculations that under the process conditions of this embodiment, the temperature sensitivity of the glass substrate is 3.1%/° C.

### Embodiment 2

Using the same method as in Embodiment 1 but substituting the etching-enhancing gas C₄F₈ with CF₄, the temperature of the electrostatic chuck 213 is controlled at 40° C. or 45° C., respectively, to prepare TiO₂ nanostructures. The measured heights of the TiO₂ nanocolumns are 126 nm and 132.9 nm, respectively.

It can be seen by calculations that under the process conditions of this embodiment, the temperature sensitivity of the glass substrate is further reduced to 1.0%/° C.

It can be seen that the CₓH_{y}F_{z} gas, as an etching-enhancing gas, can reduce the temperature sensitivity of the glass substrate, and the shorter the carbon chain and the fewer the carbon atoms, the greater the reduction in temperature sensitivity. In some embodiments, selection of any one of the etching-enhancing gases CHF₃, CH₂F₂, CH₃F, CF₄, and CH₄ can effectively promote the reduction in temperature sensitivity of the glass substrate, thereby preventing visible marks in etched glass substrates caused by local temperature differences, and enhancing the yield of metalenses.

Within a certain range, the effect of temperature control for the glass substrate depends on the backside helium gas pressure of the electrostatic chuck, and the higher the backside helium gas pressure, the better the cooling effect. To enhance temperature uniformity of the glass substrate during etching, in the present invention, the backside helium gas pressure of the electrostatic chuck is elevated to accelerate the cooling efficiency of the electrostatic chuck, thereby preventing non-uniform temperatures of the glass substrate caused by local temperature differences on the electrostatic chuck.

However, an elevated backside helium gas pressure may diminish the adsorption force of the electrostatic chuck on the glass substrate, necessitating an increase in the voltage of the electrostatic chuck to enhance the adsorption securing of the glass substrate by the electrostatic chuck. For voltage power modules of existing normal adsorption electrodes, the backside helium gas pressure does not exceed 10 Torr to adsorb the glass substrate. Therefore, in the present invention, the voltage power module of the adsorption electrode applied to the electrostatic chuck is further upgraded to a high-voltage module, enabling application of voltages exceeding 4,500 V to the adsorption electrode.

Experiments prove that during etching, the relatively appropriate range of the backside helium gas pressure of the electrostatic chuck is 18 Torr to 25 Torr. Given a backside helium gas pressure set, the voltage to the adsorption electrode is adjusted to meet the adsorption force requirements for the glass substrate. Under the aforementioned backside helium gas pressures, the glass substrate exhibits better temperature uniformity; after etching, no visible marks are observed. An excessively low backside helium gas pressure of the electrostatic chuck cannot ensure temperature uniformity of the glass substrate, while an excessively high backside helium gas pressure prevents the voltage to the adsorption electrode from meeting adsorption force requirements. Elevating the voltage needs to account for the load-bearing capacities of multiple hardware facilities, including power sources, cables, and electrodes etc. In some embodiments, the voltage is 5,000 V to 10,000 V.

In the following embodiment, a capacitively coupled plasma (CCP) reactor is adopted to prepare metalenses, and variations in the heights of nanostructures of glass wafers after etching under different voltages and backside helium gas pressures are tested, respectively.

### Embodiment 3

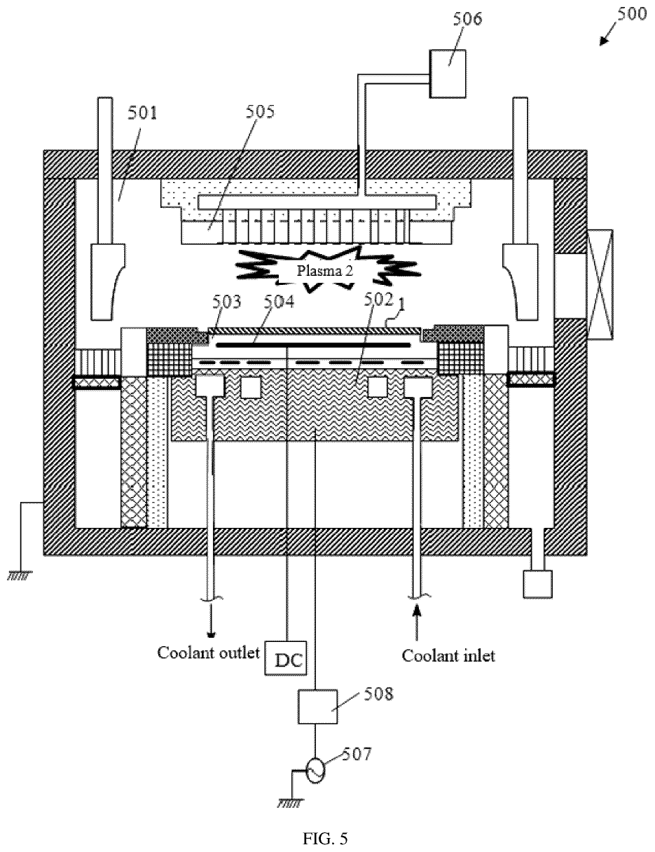

As shown in FIG. 5, a CCP reactor 500 is a device that adopts a radio frequency power source applied to electrode plates to generate plasma for etching within a reaction chamber through capacitive coupling. The CCP reactor includes a vacuum reaction chamber 501, a base 502 is disposed downstream of the vacuum reaction chamber 501, an electrostatic chuck 503 is disposed on the base 502, and an electrostatic adsorption electrode 504 is disposed within the electrostatic chuck 503 and used for generating electrostatic adsorption force to enable adsorption securing of a to-be-processed glass substrate 1 during the process.

Within the vacuum reaction chamber 501, a gas shower head 505 is disposed at the top. The gas shower head 505 is arranged opposite to the base 502. The gas shower head 505 is connected to a gas supply apparatus 506 for delivering process gases into the vacuum reaction chamber 501 and simultaneously serves as an upper electrode of the vacuum reaction chamber 501. The electrostatic chuck 503 disposed above the base 502 serves as a lower electrode of the vacuum reaction chamber 501. A reaction zone is formed between the upper electrode and the lower electrode. At least one radio frequency power source 507 is applied to either the upper electrode or the lower electrode via a matching network 508, and a radio frequency electric field is generated between the upper electrode and the lower electrode and used for dissociating reaction gases into plasma 2. The plasma 2 contains a substantial quantity of reactive species, including electrons, ions, excited-state atoms, molecules, and free radicals, etc. These reactive species can undergo diverse physical and chemical reactions with the surface of the to-be-processed substrate, thereby modifying the surface topography of the substrate and completing the etching process.

A glass substrate 1 is transferred onto the electrostatic chuck 503. As shown in FIG. 3, the glass substrate 1 includes a glass base layer 11, a TiO₂ coating 12 is formed on the surface of the glass base layer, and a patterned mask layer 13 is formed on the surface of the TiO₂ coating. The thickness of the TiO₂ coating 12 depends on the height of the TiO₂ nanostructure to be prepared, with both dimensions being equivalent.

The voltage to the adsorption electrode and the backside helium gas pressure conditions are set as shown in Table 1 below. The temperature of the electrostatic chuck 503 is controlled at 40° C. A mixture of etching gases C₄F₈ and Cl₂ (a volume ratio of Cl₂ to C₄F₈ being 4:1) is introduced into the vacuum reaction chamber 501 for 80 seconds. The etching gases are dissociated into plasma 2 under the radio frequency environment. The plasma etches the TiO₂ coating on the glass substrate 1 that is unprotected by the mask layer 13, thereby forming a TiO₂ nanostructure 10.

TABLE 1
Local Thickness Comparison of TiO₂ Nanostructures under
Different Voltages and Backside Helium Gas Pressures

| | Condition | | |
|---|---|---|---|
| | Condition 1 | Condition 2 | Condition 3 |
| | (−4,500 V HV, | (−6,500 V HV, | (−7,500 V HV, |
| | 15 T Backside | 20 T Backside | 30 T Backside |
| Item | Helium Gas) | Helium Gas) | Helium Gas) |
| TiO₂ Nanostructure | 246 | 220 | 260 |
| Thickness/nm | | | |
| TiO₂ Nanostructure | 189 | 181 | 196 |
| Thickness/nm | | | |
| Local Thickness | 57 | 39 | 64 |
| Difference/nm | | | |

From the table above, it can be seen that the condition of −6,500 V voltage and 20 Torr backside helium gas pressure is relatively ideal. Backside helium gas pressures below 18 Torr or above 25 Torr lead to significant height differences in the etched TiO₂ nanostructures on the glass substrate. In this embodiment, at the backside helium gas pressure exceeding 25 Torr in Condition 3, due to excessive gas molecular density, the intensified intermolecular collisions are likely caused, which impairs instead the cooling effect on the glass substrate.

In the metalens preparation method of the present invention, the mask layer needs to be further removed after the TiO₂ nanostructure is formed. Conventional mask layer removal methods suffice for this process.

The metalens prepared by the present invention has the advantages of thinner volume, lighter weight, lower costs, better imaging, and easier integration, providing solutions for compact integrated optical systems, enabling applications in optical elements such as VR and AR lenses.

According to the present invention, optical properties including polarization, phase, and amplitude can be modulated through adjustments to parameters of the TiO₂ nanostructures, including shapes, rotational orientations, and heights, to adapt to applications in mobile fields such as handheld devices and vehicle-mounted autonomous vehicles.

In summary, the present invention innovatively adopts a plasma etching method to prepare the TiO₂ nanostructure as the metasurface structure of metalenses on the glass base layer. Further, by adding the etching-enhancing gases CₓH_{y}F_{z}, the temperature sensitivity of the glass substrate is effectively reduced, thereby eliminating visible marks in the metalenses. Furthermore, through selection of the appropriate voltage and backside helium gas pressure conditions of the adsorption electrode, the temperature uniformity of the glass substrate during etching is enhanced, thereby further eliminating visible marks in the metalenses and increasing the yield of metalenses.

Although the content of the present invention has been described in detail through the above preferred embodiments, it should be understood that the above description should not be considered as limiting the present invention. After reading the above content, various modifications and alternatives to the present invention will be apparent to those skilled in the art. Accordingly, the protection scope of the present invention shall be limited by the appended claims.

1. A metalens preparation method, comprising:
providing a plasma processing device comprising a plasma processing chamber, wherein the plasma processing chamber is capable of providing a radio frequency environment therein and is provided with an electrostatic chuck therein;
transferring a glass substrate onto the electrostatic chuck, wherein the glass substrate comprises a glass base layer, a TiO₂ coating is formed on a surface of the glass base layer, and a patterned mask layer is disposed on a surface of the TiO₂ coating; and
introducing etching gases into the plasma processing chamber, wherein the etching gases are dissociated into plasma under the radio frequency environment, and the plasma etches the glass substrate to form a TiO₂ nanostructure.

2. The metalens preparation method according to claim 1, wherein the etching gases comprise Cl₂.

3. The metalens preparation method according to claim 1, wherein the etching gases further comprise a CₓH_{y}F_{z} gas as an etching-enhancing gas, wherein 0<x≤4, y≥0, z≥0, and y and z are not simultaneously 0.

4. The metalens preparation method according to claim 3, wherein the CₓH_{y}F_{z} gas is C₄F₈.

5. The metalens preparation method according to claim 3, wherein in the CₓH_{y}F_{z} gas, x<2.

6. The metalens preparation method according to claim 5, wherein the CₓH_{y}F_{z} gas comprises any one or more of CHF₃, CH₂F₂, CH₃F, CF₄, and CH₄.

7. The metalens preparation method according to claim 1, wherein during etching, an adsorption electrode is disposed within the electrostatic chuck, and a voltage applied to the adsorption electrode is greater than 4,500 V.

8. The metalens preparation method according to claim 7, wherein during etching, the voltage is 5,000 V to 10,000 V.

9. The metalens preparation method according to claim 1, wherein during etching, a backside helium gas pressure of the electrostatic chuck is 18 Torr to 25 Torr.

10. The metalens preparation method according to claim 1, further comprising: removing the mask layer after forming the TiO₂ nanostructure.

11. The metalens preparation method according to claim 1, wherein the mask layer is a photoresist layer;
or the mask layer comprises a photoresist layer and a hard mask layer disposed beneath the photoresist layer.

12. A metalens prepared by the metalens preparation method claim 1, comprising: a glass base layer and a TiO₂ nanostructure formed on a surface of the glass base layer, wherein the TiO₂ nanostructure is arranged in an array.

13. The metalens according to claim 12, wherein the nanostructure comprises a plurality of columns, and trenches are formed between adjacent columns.

14. metalens according to claim 12, wherein the nanostructure has a high aspect ratio that refers to a ratio of an opening width to a depth of the trenches being greater than 1:1.

15. The metalens according to claim 12, wherein a thickness of the glass base layer is 300 μm to 700 μm.

16. Use of the metalens according to claim 12, wherein the metalens is used in an optical element.

17. The use according to claim 16, wherein the metalens is used in VR and AR lenses.
